(19) United States
(12) Patent Application Publication
(10) Pub. No.: US 2014/0126145 A1
(43) Pub. Date: May 8, 2014

(54) MOUNTING APPARATUS FOR CIRCUIT BOARD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: CHIH-KUN SHIH, Santa Clara, CA (US); WAN-CHENG LUO, Shenzhen (CN); XIAO-MAO XIE, Shenzhen (CN); WEI XU, Shenzhen (CN); TAO HOU, Shenzhen (CN); YONG-GUI PAN, Shenzhen (CN)

(21) Appl. No.: 13/931,474

(22) Filed: Jun. 28, 2013

(30) Foreign Application Priority Data
Nov. 7, 2012 (CN) 2012104399350

(51) Int. Cl. H05K 5/02; H05K 7/20

(52) U.S. Cl. CPC H05K 5/02; H05K 7/20127
USPC 361/692; 361/752

(57) ABSTRACT

A mounting apparatus includes a mounting base, a securing plate attached to the mounting base, and an enclosure. The mounting base defines an opening. The securing plate includes a securing portion secured to the mounting base. The enclosure extends through the opening and is attached to the securing plate. A circuit board, used to secure a power supply, is received in the enclosure and is attached to the securing plate.

### BACKGROUND

1. Technical Field

The present disclosure relates to mounting apparatuses, more particularly to a mounting apparatus for a power supply.

2. Description of Related Art

Electronic devices comprise a mounting base and a circuit board attached to the mounting base. Because the circuit board cannot be detached from the mounting base, it is inconvenient to access and maintain. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus in accordance with an embodiment.

FIG. 2 is an assembled view of the mounting apparatus of FIG. 1.

FIG. 3 is a cross-sectional view of the mounting apparatus of FIG. 2, taken along a line III-III.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

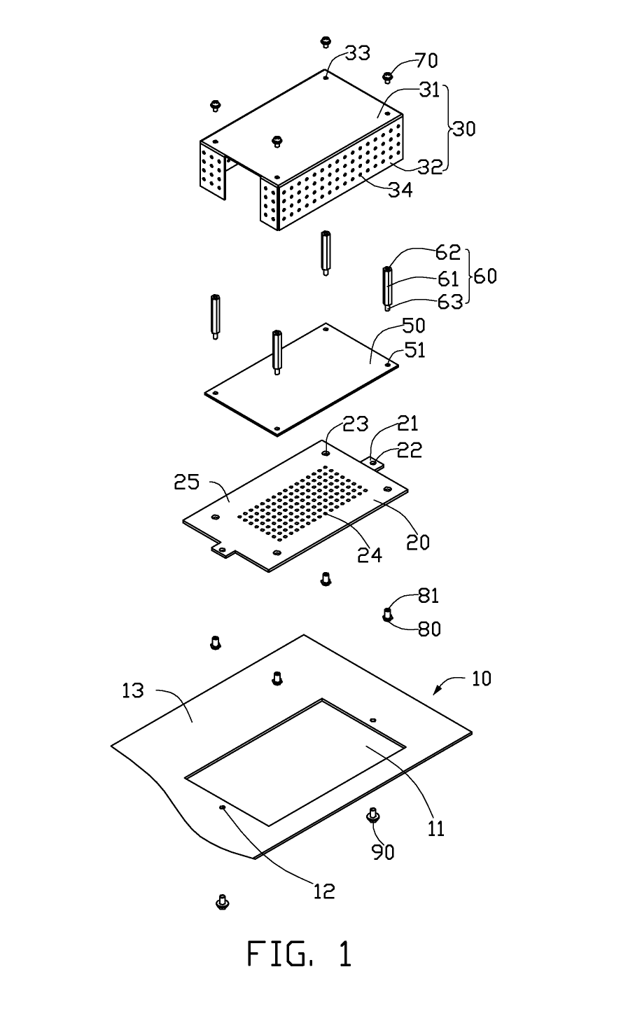

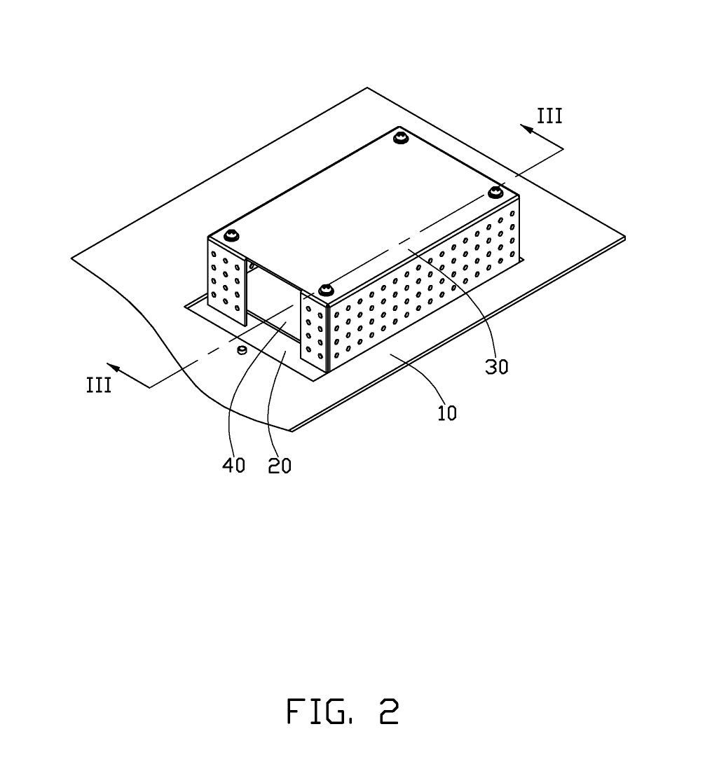

FIGS. 1 and 2 illustrate a mounting apparatus in accordance with an embodiment comprising a mounting base 10, a securing plate 20, an enclosure 30, and four fastening members 60. The securing plate 20 is attached to the mounting base 10, and the enclosure 30 is attached to the securing plate 20.

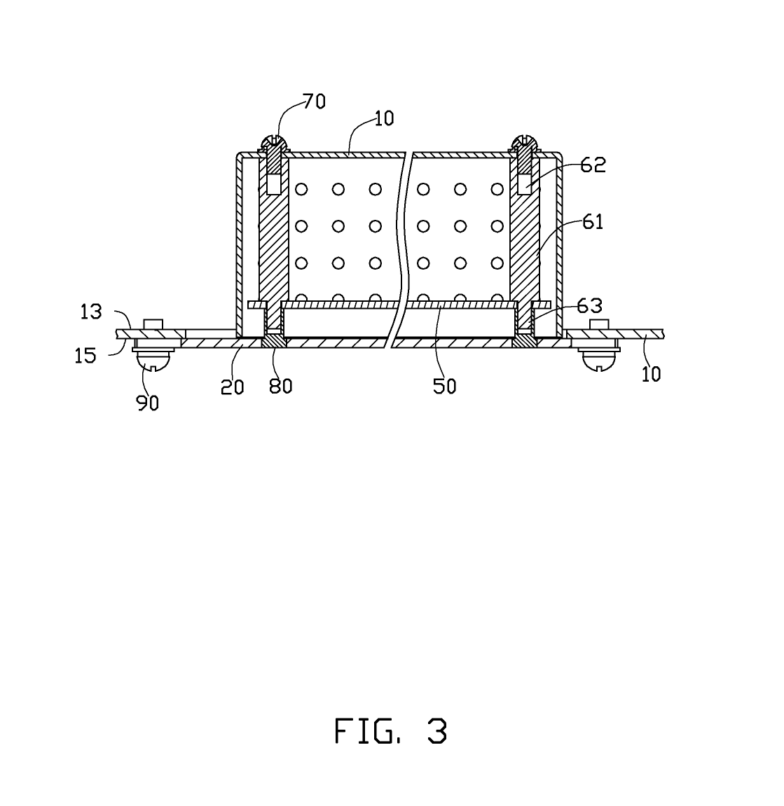

The mounting base 10 defines an opening 11 and two mounting holes 12 arranged at opposite sides of the opening 11. The mounting base 10 comprises a top surface 13 and a bottom surface 15 (see FIG. 3) opposite to the top surface 13.

The securing plate 20 comprises a main body 25 and two securing portions 21 extending from opposite edges of the main body 25. A securing hole 22 is defined in each of the two securing portions 21. Four fixing holes 23 and a plurality of first air ventilation holes 24 are defined in the main body 25. The plurality of first air ventilation holes 24 are arranged rectangularly, and the four fixing holes 23 are arranged at four corners of the main body 25.

The enclosure 30 comprises a top panel 31 and a plurality of side panels 32 extending from four edges of the top panel 31. Each of the plurality of side panels 34 is substantially perpendicular to the top panel 31. Four fastening holes 33 are defined in the top panel 31. A plurality of second ventilation holes 34 is defined in the plurality of side panels 32.

The securing plate 20 and the enclosure 30 together define a receiving space 40.

A circuit board 50 is received in the receiving space 40, and a power supply (not shown) is secured to the circuit board 50. Four through holes 51 corresponding to the four fixing holes 23 are defined in the circuit board 50.

Each of the four fastening members 60 includes an extending portion 61 and a protrusion portion 63 extending from a free end of the extending portion 61. A receiving hole 62 is defined in a top portion of the extending portion 61. In one embodiment, a diameter of the extending portion 61 is greater than a diameter of the protrusion portion 63.

FIGS. 1-3 show that in assembly, the four fastening members 60 are attached to a bottom surface of the top panel 31. The receiving holes 62 are aligned with the fastening holes 33. Four first mounting members 70 are received in the receiving holes 62 and the fastening holes 33 to secure the four fastening members 60 to the top panel 31. The securing plate 20 is attached to the bottom surface 15 of the mounting base 10. The two mounting holes 12 are aligned with the two securing holes 22, and two second mounting members 90 are received in the mounting holes 12 and the securing holes 22 to secure the securing plate 20 to the mounting base 10.

The circuit board 50 is secured to the securing plate 20. The four through holes 51 are aligned with the four fixing holes 23, and the four protrusion portions 63 extend through the corresponding four through holes 51 and the four fixing holes 23. Four securing members 80, each with a securing hole 81, receive the four protrusion portions 63. Therefore, the enclosure 30 and the circuit board 50 are secured to the securing plate 20 such that the top panel 31 is substantially parallel to the securing plate 20 and the mounting base 10. The circuit board 50 is received in the receiving space 40, and the enclosure 30 is received in the opening 11.

In disassembly, the four securing members 80 are disengaged from the four protrusion portions 63, and the protrusion portions 63 are removed from the four through holes 51 and the four fixing holes 23, such that the enclosure 30 is removed from the circuit board 50. Thus, the circuit board 50 is detached from the securing plate 20 and is easily accessible to maintain.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a mounting base defining an opening;
a securing plate secured to the mounting base to cover the opening; and the securing plate comprising a securing portion secured to the mounting base; and
an enclosure located in the opening and attached to the securing plate; a circuit board received in the enclosure and attached to the securing plate; and the circuit board adapted for securing a power supply.

2. The mounting apparatus of claim 1, wherein the mounting base comprises a bottom surface, and the securing plate is attached to the bottom surface of the mounting base.

3. The mounting apparatus of claim 1, wherein the securing plate comprises a main body, and the securing portion extends from the main body.

4. The mounting apparatus of claim 1, further comprising a fastening member; wherein the fastening member comprises an extending portion, a receiving hole is defined in the extending portion, the enclosure comprise a top panel, and a first mounting member extends through the top panel and engaged in the receiving hole.

5. The mounting apparatus of claim 4, wherein the enclosure further comprises a plurality of side panels extending from the top panel, and the plurality of side panels are attached to the securing plate and define a plurality of first air ventilation holes.

6. The mounting apparatus of claim 5, wherein the plurality of side panels is substantially perpendicular to the mounting base.

7. The mounting apparatus of claim 4, further comprising a securing member; wherein the securing member defines a securing hole, the fastening member further comprises a protrusion portion connected to the extending portion, and the protrusion portion extends through the circuit board and the securing plate and engaged in the securing hole.

8. The mounting apparatus of claim 7, wherein a diameter of the extending portion is greater than a diameter of the protrusion portion.

9. The mounting apparatus of claim 1, wherein the securing plate defines a plurality of second air ventilation holes.

10. A mounting apparatus comprising:
a mounting base defining an opening;
a securing plate attached to an bottom surface of the mounting base and covering the opening;
an enclosure located in the opening and attached to the securing plate; a circuit board received in the enclosure and attached to the securing plate; and the circuit board adapted for securing a power supply; and
a fastening member;
wherein the fastening member engages the enclosure to the securing plate.

11. The mounting apparatus of claim 10, wherein the securing plate comprises a main body and a securing portion extending from the main body, and the securing portion is secured to the mounting base.

12. The mounting apparatus of claim 10, wherein the fastening member comprises an extending portion, a receiving hole is defined in the extending portion, the enclosure comprise a top panel, and a first mounting member extends through the top panel and engaged in the receiving hole.

13. The mounting apparatus of claim 12, wherein the enclosure further comprises a plurality of side panels extending from the top panel, and the plurality of side panels are attached to the securing plate and define a plurality of first air ventilation holes.

14. The mounting apparatus of claim 13, wherein the plurality of side panels is substantially perpendicular to the mounting base.

15. The mounting apparatus of claim 12, further comprising a securing member; wherein the securing member defines a securing hole, the fastening member further comprises a protrusion portion connected to the extending portion, and the protrusion portion extends through the circuit board and the securing plate and engaged in the securing hole.

16. The mounting apparatus of claim 15, wherein a diameter of the extending portion is greater than a diameter of the protrusion portion.

17. The mounting apparatus of claim 10, wherein the securing plate defines a plurality of second air ventilation holes.
